(19) United States
(12) Patent Application Publication
(10) Pub. No.: US 2026/0371666 A1
(43) Pub. Date: Nov. 19, 2026

(54) SUPERJUNCTION TRANSISTOR DEVICE

(71) Applicant: Infineon Technologies AG, Neubiberg (DE)

(72) Inventors: Matteo DAINESE, München (DE); Anton MAUDER, Kolbermoor (DE)

(21) Appl. No.: 19/662,422

(22) Filed: Apr. 29, 2026

(30) Foreign Application Priority Data
May 15, 2025 (DE) 102025118892.0

(51) Int. Cl. H10D 62/10; H10D 30/66; H10D 62/00; H10D 84/83

(52) U.S. Cl. CPC H10D 62/111; H10D 30/66; H10D 62/054; H10D 84/839

(57) ABSTRACT

A transistor device is disclosed. The transistor device includes a drain node and a source node; a superjunction region arranged in a semiconductor body and comprising a plurality of superjunction cells each comprising a first region of a first doping type and a second region of a second doping type complementary to the first doping type; and a plurality of transistor cells. The first and second regions are arranged alternately in a first direction of the semiconductor body. The second regions are coupled to the source node. Each first region is coupled to the source node via at least one of the transistor cells and is coupled to the drain node. The superjunction cells comprise at least two different groups of superjunction cells that are different from each other in terms of the depletion voltage of the respective superjunction cells.

### RELATED APPLICATION

This application claims priority to German Patent Application No. 102025118892.0, filed on May 15, 2025, entitled “SUPERJUNCTION TRANSISTOR DEVICE”, which is incorporated by reference herein in its entirety.

### SUMMARY

This disclosure relates in general to a superjunction transistor device.

A superjunction transistor device includes a superjunction region and a plurality of transistor cells. The superjunction region includes a plurality of first regions of a first doping type (conductivity type) and a plurality of second regions of a second doping type (conductivity type) complementary to the first doping type. The first regions are often referred to as drift regions and the second regions are often referred to as compensation regions. The first and second regions are arranged alternatingly and a PN junction is formed between each first region and an adjacent second region.

Each of the first regions is coupled to a source node of the transistor device via at least one of the transistor cells and is coupled to a drain node. Furthermore, each of the second regions is coupled to the source node.

The superjunction transistor device can be operated in a conducting state (on-state) and a blocking state (off-state). The operating state of the transistor device is governed by the operating state of the transistor cells, wherein the transistor device is in the conducting state when the transistor cells are in a conducting state (on-state) and in the blocking state when the transistor cells are in a blocking state (off-state).

In the conducting state, the transistor cells allow a current to flow between a drain node and the source node through the first regions (drift regions) of the superjunction region when a corresponding voltage (drain-source voltage) is applied between the drain node and the source node. In the blocking state, the transistor cells prevent a current flow through the first regions. Furthermore, in the blocking state, the drain-source voltage is such that PN-junctions between the first and second regions are reverse biased so that depletion regions (space charge regions) expand in the first and second regions.

An output capacitance (sometimes referred to as Coss) of a superjunction transistor device, which is effective when the transistor device is in the off-state, is significantly dependent on a junction capacitance of the overall PN junction formed between the first and second regions of the superjunction region. This output capacitance is dependent on the magnitude of the drain-source voltage and is highly nonlinear. When the transistor device is in the off-state and the drain source voltage starts to increase, the output capacitance is initially high. As the drain-source voltage increases, the output capacitance decreases as the depletion region in the first and second regions expands. Once the first and second regions are entirely depleted, the output capacitance drops rapidly. Dependent on the specific design of the transistor device, the drop of the output capacitance may occur when the magnitude of the drain-source voltage is in the range of several 10 volts, although the voltage blocking capability of the device may be several hundred volts or higher, such as between 400V and 3.3 kV, or even more.

A superjunction transistor device may be used as an electronic switch for controlling a current through a load connected in series with the superjunction transistor device. Controlling the current through the load may include modulating the current by operating the superjunction transistor device in a switched mode at a high switching frequency, such as higher than 1 kHz or higher than 10 KHz. Operating the superjunction transistor device in the switched mode includes alternatingly operating the transistor device in an on-state (conducting state) and an off-state (blocking state). The nonlinearity of the output capacitance, and in particular the rapidly decreasing output capacitance at a rather low drain-source voltage, may result in high voltage transients of the drain-source voltage when the operating state of the superjunction transistor device changes from an on-state to an off-state, or vice versa. In certain applications such high voltage transients are undesirable. In motor drive applications, for example, high voltage transients may jeopardize the reliability of motor windings.

There is therefore a need for an improved superjunction transistor device, in particular a superjunction transistor device with a smoother output capacitance characteristic.

Examples disclosed herein relate to transistor devices. The transistor according to one example includes a drain node and a source node; a superjunction region arranged in a semiconductor body and including a plurality of superjunction cells each including a first region of a first doping type and a second region of a second doping type complementary to the first doping type; and a plurality of transistor cells. The first and second regions are arranged alternately in a first direction of the semiconductor body. The second regions are coupled to the source node. Each of the first regions is coupled to the source node via at least one of the transistor cells and is coupled to the drain node. The superjunction cells include at least two different groups of superjunction cells that are different from each other in terms of the depletion voltage of the respective superjunction cells.

The transistor device according to another example includes a drain node and a source node; a superjunction region arranged in a semiconductor body and including a plurality of superjunction cells each including a first region of a first doping type and a second region of a second doping type complementary to the first doping type; and a plurality of transistor cells. The first and second regions are arranged alternately in a first direction of the semiconductor body. The second regions are coupled to the source node. Each of the first regions is coupled to the source node via at least one of the transistor cells and is coupled to the drain node. The superjunction cells include at least two different groups of superjunction cells wherein each superjunction cell has a first average dopant dose and a second average dopant dose, and wherein the superjunction cells of the at least two different groups are different from each other in terms of at least one of the first and second average dopant doses.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 shows a vertical cross sectional view of a superjunction transistor device that includes a superjunction region and a plurality of transistor cells, the superjunction region including a plurality of superjunction cells each including a first region and a second region;

FIG. 2 schematically illustrates the dependencies of the output capacitance and of the feedback capacitance on the drain-source voltage in a conventional superjunction transistor device;

FIGS. 3A-3C illustrate the expansion of the depletion region in superjunction cells of a conventional superjunction transistor device as the drain-source voltage increases;

FIG. 4 illustrates the dependency of the output capacitance on the drain-source voltage in a superjunction transistor device that includes at two different groups of superjunction cells;

FIGS. 5A-5B and 6 illustrate one example of how two different groups of superjunction cells may be implemented;

FIGS. 7A-7B and 8 illustrate another example of how two different groups of superjunction cells may be implemented;

FIGS. 9A-9B and 10 illustrate another example of how two different groups of superjunction cells may be implemented;

FIGS. 11A-11D illustrate one example of a method for forming the first and second regions of the superjunction cells, the method including implanting dopant atoms into one epitaxial layer;

FIGS. 12A-12B illustrate another example of a method for forming the first and second regions of the superjunction cells, the method including implanting dopant atoms into several epitaxial layers;

FIG. 13 illustrates doping profiles of dopant atoms in the first and second regions that may be obtained by a method according to FIGS. 23A-23B;

FIG. 14 illustrates how the implementation of the different groups of superjunction cells in the examples illustrated in FIGS. 7A-7B, 8 and 9A-9B, 10 may affect the voltage blocking capability of the superjunction transistor device;

FIG. 15 illustrates the dependencies of the output capacitance and of the feedback capacitance on the drain-source voltage in a superjunction transistor device that includes more than two different groups of superjunction cells;

FIGS. 16-22 illustrate different examples of how the different groups of superjunction cells may be implemented;

FIGS. 23-24 illustrate one example of how the superjunction cells of the different groups may be arranged next to each other;

FIGS. 25A-25B schematically illustrate transistor cells according to one example;

FIGS. 26A-26B schematically illustrate transistor cells according to another example;

FIGS. 27-28 illustrate a vertical cross-sectional view of a superjunction region according to further examples;

FIG. 29 schematically illustrates another example of a superjunction transistor device, the superjunction transistor device being a lateral superjunction transistor device.

### DETAILED DESCRIPTION

In the following detailed description, reference is made to the accompanying drawings. The drawings form a part of the description and for the purpose of illustration show examples of how the disclosed subject matter may be used and implemented. It is to be understood that the features of the various embodiments described herein may be combined with each other, unless specifically noted otherwise.

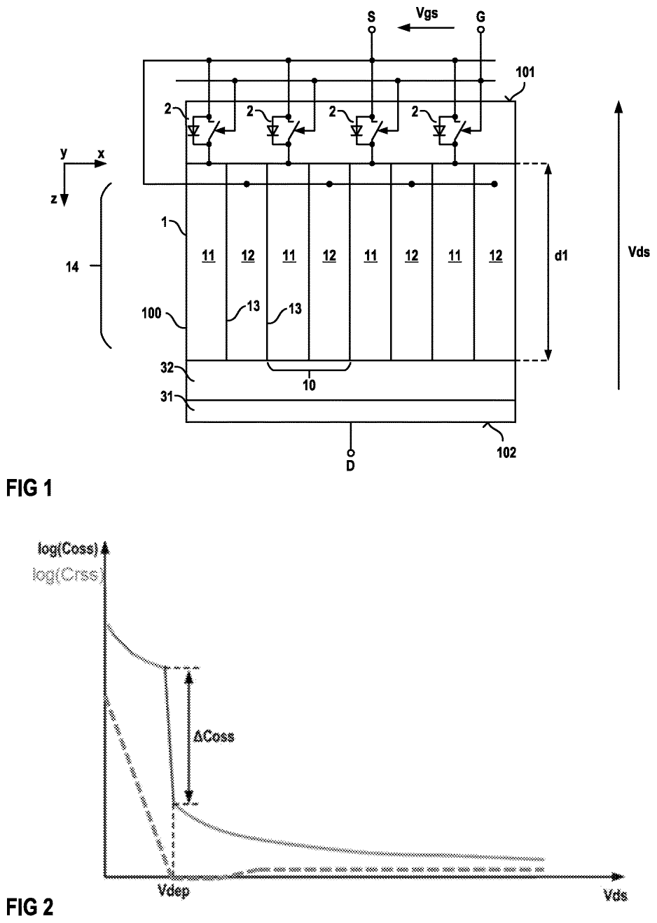

FIG. 1 schematically illustrates a superjunction transistor device according to one example. More specifically, FIG. 1 schematically illustrates a vertical cross-sectional view of a part of the transistor device. The transistor device includes a semiconductor body 100 with a first surface 101 and a second surface 102 opposite the first surface. FIG. 1 illustrates a vertical cross-sectional view of the semiconductor body 100 in a vertical section plane which is substantially perpendicular to the first and second surfaces 101, 102.

According to one example, the semiconductor body 100 includes a monocrystalline semiconductor material. The monocrystalline semiconductor material is silicon (Si) or silicon carbide (SiC), for example.

The semiconductor body 100 further includes a first lateral direction x and a second lateral direction y, the second lateral direction y being substantially perpendicular to the first lateral direction x. The first and second lateral directions are substantially parallel to the first and second surfaces 101, 102 and perpendicular to the vertical direction z. With regard to the first lateral direction x it should be noted that, unless stated otherwise, “first lateral direction x” includes both the direction as indicated by the arrow labelled with x in the figures and the opposite direction. The same applies to the second lateral direction y, which includes both the direction as indicated by the arrow labelled with y in the figures and the opposite direction, and the vertical direction z, which includes both the direction as indicated by the arrow labelled with z in the figures and the opposite direction.

The transistor device illustrated in FIG. 1 is a vertical transistor device. This includes that in an on-state of the transistor device current flows substantially in the vertical direction z through the semiconductor body 100. This is explained in detail herein further below.

Referring to FIG. 1, the superjunction transistor device includes a superjunction region 1. The superjunction region 1 includes first regions 11 of a first doping type and second regions 12 of a second doping type complementary to the first doping type. The first regions 11 and the second regions 12 are arranged alternately in a direction perpendicular to the current flow direction. In the example illustrated in FIG. 1, the first and second regions 11, 12 are arranged alternately in the first lateral direction x. The first regions 11 of the superjunction region 1 may also be referred to as a drift regions and the second regions 12 may also be referred to as compensation regions.

A pair of regions including a first region 11 and an adjacent second region 12 with a PN junction 13 formed therebetween is referred to as superjunction cell 10 in the following.

As used herein, a doped region of a first doping type, such as a first region 11 of the superjunction region 1, is a doped region having an effective doping concentration of the first doping type, and a doped region of a second doping type, such as a second region 12 of the superjunction region 1, is a doped region having an effective doping concentration of the second doping type.

The first and second regions 11, 12 may be elongated in the second lateral direction y. Elongated as used herein includes that a length of the first and second regions 11, 12 in the second lateral direction y is much larger than a respective width of the first and second regions 11, 12. According to one example, the length is at least 10 times, at least 50 times, at least 100 times, or at least 500 times the width. The length is the dimension of the first and second regions 11, 12 in the second lateral direction y. The width is the dimension of the first and second regions 11, 12 in the first lateral direction x. Furthermore, the first and second regions 11, 12 are not necessarily contiguous in the second lateral direction y, but each of the first and second regions 11, 12 may include one or more elongated sections arranged spaced apart from each other in the second lateral direction y.

According to another example, the first regions 11 or the second regions 12, in horizontal plane perpendicular to the vertical direction z, have a rotational symmetric shape, e.g. round, square or hexagonal shape, and may be arranged e.g. in square or hexagonal geometry.

Referring to FIG. 1, the transistor device further includes a drain region 31 of the first doping type. The drain region 31 is arranged between the superjunction region 1 and the second surface 102 and may adjoin the second surface 102. The drain region 31 forms a drain node D or is connected to a drain node D of the transistor device.

According to one example, as illustrated in FIG. 1, the drain region 31 is spaced apart from the superjunction region 1 in the vertical direction z. In this example, a buffer region 32 of the first doping type is arranged between the drain region 31 and the superjunction region 1. A doping concentration of the buffer region 32 is lower than a doping concentration of the drain region 31, such as more than two orders of magnitude lower than the doping concentration of the drain region 31. The doping concentration of the buffer region 32 is in a range of between 1E16 cm⁻³ and 1E18 cm⁻³ and the doping concentration of the drain region is higher than 1E18 cm⁻³, for example.

Referring to FIG. 1, the transistor device further includes transistor cells 2 that are at least partially integrated in the semiconductor body 100. “At least partially integrated” includes that at least active device regions, such as source and body regions (explained herein further below) are integrated in the semiconductor body 100. Each transistor cell 2 is coupled between a source node S of the transistor device and at least one of the first regions 11 of the superjunction region 1. Furthermore, each transistor cell 2 is configured to control a conducting channel between the source node S and the respective first region 11. The transistor cells 2 are not illustrated in detail in FIG. 1. Instead, in FIG. 1, each of the transistor cells 2 is represented by a controllable electronic switch with a parallel diode, which symbolize the functionality of the transistor cells. A detailed example of the transistor cells 2 is explained herein further below.

The transistor device illustrated in FIG. 1 can be operated in a forward biased mode (forward biased state) or a reverse biased mode (reverse biased estate). The reverse biased mode may also be referred to as diode mode of the transistor device. The transistor device is in the reverse biased mode when a polarity of a voltage applied between the drain node D and the source node S is such that the diodes in the transistor cells 2 are forward biased; and the transistor device is in the forward biased mode when the polarity of the voltage applied between the drain node D and the source node S is such that the diodes in the transistor cells 2 are reverse biased. In the forward biased mode, the transistor device can be operated in an on-state or an off-state. The transistor device is in the on-state when there are conducting channels in the transistor cells 2 between the source node S and the first regions 11 of the first superjunction region 1; and the transistor device is in the off-state when the conducting channels are interrupted.

According to one example, the transistor device is a gate-controlled transistor device. In this example, the presence of conducting channels in the transistor cells 2 is dependent on a voltage (gate-source voltage) applied between a gate node G and the source node S, so that the transistor device is in the on-state or the off-state dependent on the gate-source voltage.

The second regions 12 of the superjunction region 1 are coupled to the source node S. This coupling of the second regions 12 to the source node S is only schematically illustrated in FIG. 1. According to one example, the second regions 12 are coupled to the source node S via the transistor cells 2. According to one example, the second regions 12 are in electrical contact with regions (such as body regions) of the transistor cells 2 forming the anodes of the diodes shown on FIG. 1. One example of coupling the second regions 12 to the source node S is explained herein further below. Furthermore, the first regions 11 of the first superjunction region 1 are coupled to the drain region 31 and the drain node D. The first regions 11 are coupled to the drain region 31 either directly by adjoining the drain region 31, or through the buffer region 32.

When the transistor device is in the on-state by applying a suitable drive voltage (gate-source voltage) Vgs between the gate node and the source node and when a respective voltage (drain-source voltage) is applied between the drain node D and the source node S, a current can flow from the source node S via the transistor cells 2 and the first regions (drift regions) 11 of the superjunction region to the drain region 31 and the drain node D. In the first regions 11, the current substantially flows in the vertical direction z, which is the current flow direction in the transistor device according to FIG. 1.

When the transistor device is in the off-state and a voltage is applied between the drain node D and the source node S space charge regions (depletion regions) expand in the first regions 11 and the second regions 12 beginning at PN junctions 13 formed between adjacent first and second regions 11, 12. This enables the first superjunction region 1 to substantially absorb the voltage applied between the drain node D and the source node S of the transistor device. This is a well-known operating principle of a superjunction device.

In the transistor device according to FIG. 1, PN junctions between adjacent first and second regions 11, 12 extend in the vertical direction z and the second lateral direction y. The depletion regions substantially expand in directions perpendicular to the PN junctions 13, so that in the transistor device according to FIG. 1, the depletion regions substantially expand in the first lateral direction x.

It should be noted that “PN junction” as used herein denotes any kind of junction (border) between adjacent first and second regions 11, 12. In particular, the PN junction is at a position between adjacent first and second regions at which an effective doping concentration is substantially zero. The presence of the PN junction 13 not necessarily requires that adjacent first and second regions 11, 12 adjoin one another. It is also possible that adjacent first and second regions are spaced apart from each other.

Each of the first regions 11 and the second regions 12 has a lateral dopant dose. The lateral dopant dose is the integral of the effective doping concentration of the respective first region 11 or second region 12 in the direction in which the first and second regions 11, 12 are arranged alternately. Thus, in the transistor device according to FIG. 1, the lateral dopant dose of a first region 11 is the integral of the effective doping concentration of first type dopant atoms in the first lateral direction x, and the lateral dopant dose of a second region 12 is the integral of the effective doping concentration of second type dopant atoms in the first lateral direction x.

The lateral dopant dose may vary in the vertical direction z and in the second lateral direction y. For the purpose of explanation, it is assumed that at a certain vertical position z the lateral dopant dose of a certain first region 11 is the same at each lateral position in the second lateral direction y and that at a certain vertical position the lateral dopant dose of a certain second region 12 is the same at each lateral position in the second lateral direction y. Thus, in the following, lateral dopant dose of a first region 11 denotes the lateral dopant dose of the first region 11 at a certain vertical position, and lateral dopant dose of a second region 12 denotes the lateral dopant dose of the second region 12 at a certain vertical position.

In the following, the first lateral dopant dose of a superjunction cell 10 denotes the lateral dopant dose of the first region 11 of the superjunction cell 10, and the second lateral dopant dose of a superjunction cell 10 denotes the average lateral dopant dose of the second region 12 of the superjunction cell 10. Referring to the above, the first and second lateral dopant doses are doses at a certain position in the current flow direction of the respective first or second region and may vary in the current flow direction.

The expansion of the depletion regions in the first and second regions 11, 12 is associated with an electric field, which is referred to as lateral electric field in the following. A pair of neighboring first and second regions 11, 12 is entirely depleted at a certain vertical position when the depletion region in the first lateral direction x has reached the middle of each of the first and second regions 11, 12. A magnitude of the lateral electric field reaches a maximum when neighboring first and second regions 11, 12 are entirely depleted.

The value of the maximum of the electric field at a certain vertical position of a PN junction formed between adjacent first and second regions 11, 12 is dependent on a lateral dopant dose of the adjacent first and second regions 11, 12 at the respective vertical position. Basically, the higher the lateral dopant dose at a respective vertical position z the higher the maximum Emax of the electric field.

According to one example, the lateral dopant doses of adjacent first and second regions 11, 12 are selected such that the maximum of the field strength of the electric field is below a critical value. When the field strength would reach the critical value an avalanche breakdown may occur, which is undesirable. The critical value of the electric field and the dopant dose that may result in the electric field reaching the critical value is dependent on the type of semiconductor material of the semiconductor body 100.

In 4H SiC, for example, the lateral dopant dose of a P-type and an N-type region adjoining one PN junction that may result in an avalanche breakdown is approximately between 1.5 . . . 2.5·10¹³ cm⁻². This lateral dopant dose may also be referred to as critical lateral dopant dose or breakdown charge.

The semiconductor body 100 may have an inner region, which is a region in which the transistor cells are arranged, and an edge region surrounding the inner region and including an edge termination structure, for example. This is basically known, so that no further explanation is required in this regard. In the inner region each first region 11 is arranged between two second regions 12 and each second region 12 is arranged between two first regions 11. In this case, a pair of neighboring first and second regions 11, 12 is entirely depleted when the depletion region in the first lateral direction x has reached the middle of each of the first and second regions 11, 12. Thus, each of the first and second regions 11, 12, at each vertical position, may have up to twice the critical lateral dopant dose in order to avoid an avalanche breakdown. According to one example, however, the lateral dopant dose in each of the first and second regions 11, 12 at each vertical position is adjusted to be not more than one time the critical lateral dopant dose in order to reliably prevent an avalanche breakdown during operation of the transistor device despite fluctuations in the manufacturing process that may result in undesired variations of the lateral dopant dose.

The PN junctions formed between the first and second regions 11, 12 of the transistor device form a significant part of an output capacitance Coss off the transistor device. The output capacitance is a capacitance of the transistor device which is effective between the drain node D the source node S of the transistor devices and includes the drain-source capacitance Cps and the gate-grain capacitance CGD of the transistor device.

In the inner region of a conventional superjunction transistor device, in which the first regions 11 have the same lateral dopant dose at the same vertical position and in which the second regions 12 have the same lateral dopant dose at the same vertical position, the output capacitance Coss is highly dependent on the drain-source voltage Vds and rapidly decreases when the drain source-voltage Vds reaches a voltage level at which the first and second regions 11, 12 are entirely depleted. This is illustrated in FIG. 2.

FIG. 2 schematically illustrates on a logarithmic scale the dependency of the output capacitance Coss on the drain source voltage Vds when the transistor device is in the off-state. As can be seen from FIG. 2, the output capacitance Coss decreases when the drain-source voltage increases, wherein the output capacitance rapidly decreases (drops) when the drain-source voltage reaches a voltage level Vdep at which the first and second regions 11, 12 are entirely depleted. The voltage at which the voltage level Vdep (or, briefly, the voltage) at which the first and second regions 11, 12 are entirely depleted is referred to as depletion voltage Vdep in the following. In FIG. 1, ΔCoss denotes the drop in the drop in the output capacitance Coss when the drain-source voltage Vds reaches the depletion voltage Vdep.

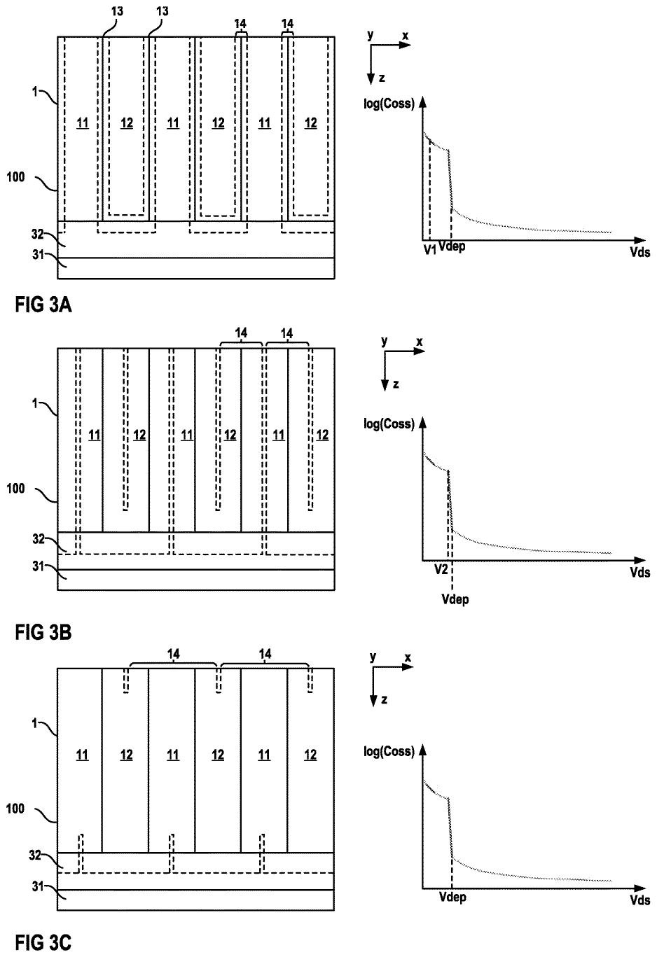

FIGS. 3A-3C schematically illustrate the expansion of the depletion region in the first and second regions 11, 12 of the superjunction region 1 and the corresponding output capacitance Coss at different voltage levels of the drain source voltage Vds. For the ease of illustration, each of FIGS. 3A-3C only shows a portion of the superjunction region 1 and adjacent portions of the drain and buffer regions 31, 32. The transistor cells 2 are not illustrated. Furthermore, in FIGS. 3A-3C reference number 14 denote the depletion regions and the dashed lines illustrate the borders of the depletion regions at the different voltage levels of the drain source voltage Vds.

FIG. 3A illustrates the situation at a first level V1 of the drain-source voltage, the first voltage level V1 being much lower than the depletion voltage Vdep, such as less than 50% of the depletion voltage Vdep; FIG. 3B illustrates the situation at a second level V2 of the drain-source voltage Vds, the second voltage level V2 being close to the depletion voltage Vdep; and FIG. 3C illustrates the situation when the drain-source voltage Vds reaches the depletion voltage Vdep.

As can be seen from FIGS. 3A-3B, the depletion region 14 expands substantially in the first lateral direction x when the drain-source voltage Vds is below the depletion voltage Vdep and increases. If, for example, the doping concentrations in the first and second regions 11, 12 are substantially homogeneous in the first lateral direction x, the dimension of the space charge region 14 in the first lateral direction x is essentially proportional to the voltage level of the drain-source voltage Vds.

As can be seen from FIG. 3C, the first and second regions 11, 12 are entirely depleted as the drain-source voltage Vds reaches the depletion voltage Vdep. “Entirely” in this context includes that the first and second regions 11, 12 are depleted of charge carriers except for, at most, small regions close to the transistor cells 2 and the drain and buffer regions 31, 32.

The depletion voltage Vdep is in the range of several 10 volts, for example, although the voltage blocking capability of the device may be several hundred volts or higher. According to one example, the transistor device is based on SiC and the voltage blocking capability is between 400V and 3.3 kV, or even more. The voltage blocking capability is the maximum of drain-source voltage Vds the transistor device can withstand in the off-state and is substantially dependent on a dimension of the superjunction region 1 in the vertical direction Z.

A superjunction transistor device may be used as an electronic switch for controlling a current through a load connected in series with the superjunction transistor device. Controlling the current through the load may include modulating the current by operating the superjunction transistor device in a switched mode at a high switching frequency, such as higher than 1 kHz or higher than 10 kHz. The nonlinearity of the output capacitance Coss, and in particular the rapidly decreasing output capacitance Coss at the rather low depletion voltage Vdep, may result in high voltage transients of the drain-source voltage Vds when the superjunction transistor device is operated in the switched mode. In certain applications such high voltage transients are undesirable. In motor drive applications, for example, high voltage transients may jeopardize the reliability of motor windings.

There is therefore a need for a superjunction transistor device with a smoother decrease of the output capacitance Coss as the drain-source voltage Vds increases.

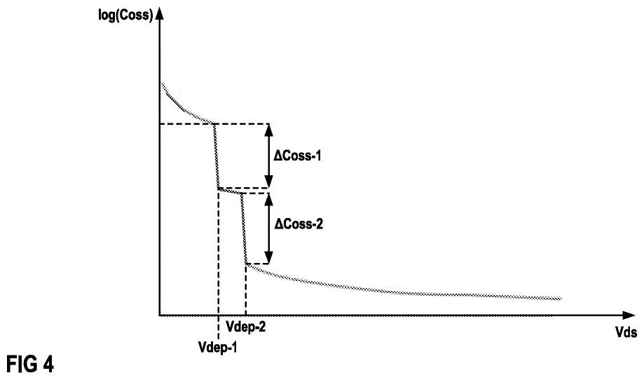

According to one example, the transistor device according to FIG. 1 is implemented to have at least two different groups of superjunction cells 10 with different depletion voltages. The dependency of the output capacitance Coss on the drain-source voltage Vds of a superjunction transistor device of this type is illustrated in FIG. 4. In the following, the depletion voltage of a superjunction cell 10 is the voltage at which at least one of the first and second regions 11, 12 of the superjunction cell 10 is entirely depleted. “Entirely depleted” as used herein in context with a superjunction cell includes that at least 80%, at least 90%, or at least 95% of at least one of the first and second regions 11, 12 of the superjunction cell 10 are depleted.

FIG. 4 schematically illustrates the dependency of the output capacitance Coss of a superjunction transistor device that includes two groups of superjunction cells 10, a first group of superjunction cells having a first depletion voltage Vdep-1, and a second group of superjunction cells having a second depletion voltage Vdep-2 different from the first depletion voltage Vdep-1. Just for the purpose of illustration, the second depletion voltage Vdep-2 is higher than the first depletion voltage Vdep-1.

As can be seen from FIG. 4, the output capacitance Coss has two steps where the output capacitance Coss rapidly decreases, a first step at the first depletion voltage Vdep-1 and a second step at the second depletion voltage Vdep-2. As compared to only one step (see ΔCoss in FIG. 2) in a transistor device of the same size and the same voltage blocking capability, the two steps in the transistor device according to FIG. 4 have a lower “height” ΔCoss-1, ΔCoss-2 and occur at different drain-source voltages Vdep-1, Vdep-2, so that an overall decrease of the output capacitance Coss is smoother than in the conventional superjunction transistor device (see FIG. 2).

The height of the steps ΔCoss-1, ΔCoss-2 is dependent on the number of superjunction cells included in the respective group of superjunction cells. Basically, the higher the number of superjunction cells included in a respective group, the larger the height of the respective step. Equivalently, the lower the number of superjunction cells included in a respective group, the lower the height of the respective step.

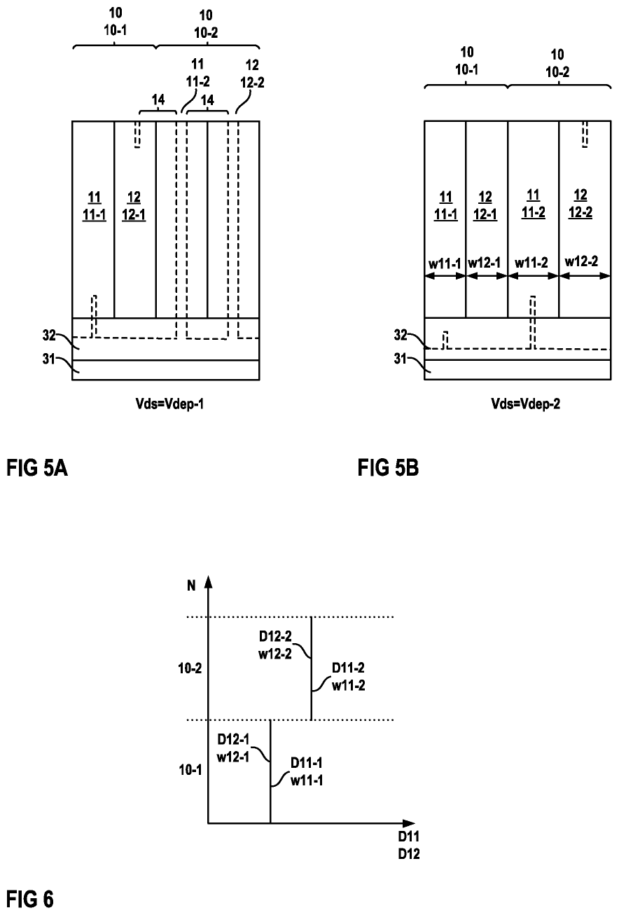

It should be noted that implementing the transistor device with only two different groups of superjunction cells, resulting in two different depletion voltages Vdep-1, Vdep-2, as illustrated in FIG. 4 and as explained with reference to FIGS. 5A-5B, 6, 7A-7B and 8 in the following, is just for the purpose of illustration and explanation. A smoother decrease of the output capacitance Coss can be achieved by implementing the transistor device with more than two different groups of superjunction cells. In the following, different groups of superjunction cells are groups of superjunction cells with different depletion voltages.

Referring to the above, the depletion voltage of a superjunction cell 10 is dependent on the lateral dopant doses of the first and second regions 11, 12 of the superjunction cell 10. The first region 11 is entirely depleted when essentially at each vertical position of the first region 11 the first region 11 is depleted of charge carriers. Equivalently, the second region 12 is entirely depleted when essentially each vertical position of the second region 12 the second region 12 is depleted of charge carriers.

A superjunction cell 10 can be implemented such that both the first region 11 and the second region 12 are entirely depleted when the drain-source voltage Vds reaches the respective depletion voltage. In this example, essentially each first type dopant atom (first type charge carrier) in the first region has a second type dopant atom (second type charge carrier) as a corresponding counterpart in the second region 12. A superjunction cell 10 of this type is referred to as balanced superjunction cell in the following.

A superjunction cell 10 can also be implemented such that only one of the first region 11 and the second region 12 is entirely depleted when the drain-source voltage reaches the respective depletion voltage. In this example, only dopant atoms (charge carriers) in the one of the first and second regions 11, 12 that is entirely depleted finds a corresponding counterpart in the other one of the first and second regions 11, 12. The other one of the first and second regions 11, 12 is not entirely depleted when the drain-source voltage reaches the depletion voltage. A superjunction cell 10 of this type is referred to as imbalanced superjunction cell in the following.

In an imbalanced superjunction cell 10, as the drain-source voltage further increases, dopant atoms in the other one of the first and second regions 11, 12 find corresponding counterparts either in the drain and/or buffer regions 31, 32 when the other one of the regions is the second region 12, or in the body regions (explained herein further below) of the transistor cells 2 when the other one of the regions is the first region 11.

FIGS. 5A-5B schematically illustrate the operating principle of a superjunction transistor device with two different groups of balanced transistor cells. Each of FIGS. 5A-5B shows a vertical cross-sectional view of one superjunction cell of the first group 10-1 and one superjunction cell of the second group 10-2. The superjunction cell of the first group 10-1 is also referred to as first superjunction cell 10-1 and the superjunction cell of the second group 10-2 is also referred to as second superjunction cell 10-2 in the following.

FIG. 5A illustrates an operating scenario in which the transistor device is in the off-state and the increasing drain-source voltage Vds has reached the first depletion voltage Vdep-1 so that the first region 11-1 and the second region 12-1 of the balanced first transistor cell are entirely depleted, while the first region 11-2 and the second region 12-2 of the balanced second superjunction cell with the higher depletion voltage Vdep-2 have not yet been depleted. FIG. 5B illustrates the operating scenario in which the further increasing drain-source voltage Vds has reached the second depletion voltage Vdep-2, so that also the first and second regions 11-2, 12-2 of the second superjunction cell are depleted.

The depletion voltage of a superjunction cell 10 and the balancing status, that is, whether the superjunction cell is balanced or imbalanced, can be adjusted by suitably adjusting the lateral dopant doses of the first and second regions 11, 12 of the respective superjunction cell 10. This is explained in the following.

Each of the first and second regions 11, 12 has an average dopant dose, which is briefly referred to as average dose in the following. The average dose is the average of the lateral dopant dose of the respective region 11, 12 in a first section 14 (see FIG. 1) of the superjunction region 1 The first section extends over more than 70%, 80%, 90% or 95% of the superjunction region 10 in the current flow direction. The first section 14 may be spaced apart from at least one of a first end and a second end of the superjunction region 10, the first end facing the drain and buffer regions 31, 32 and the second end facing the transistor cells.

In the following, the first average dose of a superjunction cell 10 is the average dose of the first region 11 of the superjunction cell 10, and the second average dose of a superjunction cell 10 is the average dose of the second region 11 of the superjunction cell 10. The first average dose is the average of the first lateral dopant dose at a certain position in a direction perpendicular to the current flow direction and perpendicular to the direction in which the first and second regions 11, 12 are arranged alternately. The second average dose is the average of the second lateral dopant dose at a certain position in the direction perpendicular to the current flow direction and perpendicular to the direction in which the first and second regions 11, 12 are arranged alternately. In the example illustrated in FIG. 1, the direction perpendicular to the current flow direction and perpendicular to the direction in which the first and second regions 11, 12 are arranged alternately is the second lateral direction y.

According to one example, the superjunction region 1 is implemented such that in each first region 11 the first average dose is the same at each position in the second lateral direction y of the respective first region 11 and such that in each second region 12 the second average dopant dose is the same at each position in the second lateral direction y of the respective second region 12. Furthermore, according to one example, the adjacent first and second regions 11, 12 of a superjunction cell 10 have the same dimension d1 in the vertical direction z (see FIG. 1) and the same dimension in the second lateral direction y.

The unit of the first and second lateral dopant doses and the first and second average (dopant) doses is dopant atoms per square centimeter (cm⁻²). The overall amount of first type dopant atoms in a first region 11 in the first section 14 is given by the first average dose multiplied with the dimension of the first section 14 in the current flow direction (the vertical direction z in the example according to FIG. 1) and multiplied with the dimension of the first region 11 in the direction perpendicular to the current flow direction and perpendicular to the direction in which the first and second regions 11, 12 are arranged alternately (the second lateral direction y in the example illustrated in FIG. 1). Equivalently, the overall amount of second type dopant atoms in a second region 12 in the first section 14 is given by the second average dose multiplied with the dimension of the first section 14 in the current flow direction (the vertical direction z in the example according to FIG. 1) and multiplied with the dimension of the second region 12 in the direction perpendicular to the current flow direction and perpendicular to the direction in which the first and second regions 11, 12 are arranged alternately (the second lateral direction y in the example illustrated in FIG. 1).

According to one example, a superjunction cell 10 being balanced includes that the first average dose (of the first region 11) at least approximately equals the second average dose (of the second region 12). It should be noted that for various reasons, in a balanced superjunction cell 10, lateral dopant doses of the first and second regions 11, 12 may be different from each other towards the first end and/or the second end of the superjunction region 10, so that a balanced superjunction cell 10 may be imbalanced in regions close to the first end and the second end. For this reason, only the doping situation in the first section 14 is taken into account to determine the balancing situation (balanced or imbalanced). Furthermore, the doping situation in the first section 14, which covers the largest part of the superjunction region 10, essentially determines the depletion voltage of the individual superjunction cells 10.

In the following, D11 followed by an identifier, such as −1, −2, . . . , denotes the first average dose of a superjunction region 10, and D12 followed by an identifier, such as −1, −2, . . . , denotes the second average dose of the superjunction region 10.

Referring to FIG. 5 and as explained above, the superjunction cell of the first group 10-1 is balanced and the superjunction cell of the second group 10-2 is balanced. Referring to FIG. 6 this includes that the first average dose D11-1 of the first group superjunction cells 10-1 at least approximately equals the second average dopant dose D12-1 of the first group superjunction cells 10-1 and the first average dose D11-2 of the second group superjunction cells 10-2 at least approximately equals the second average dopant dose D12-2 of the second group superjunction cells 10-1.

Furthermore, referring to FIG. 6, in the second group superjunction cells 10-2, which have a second depletion voltage Vdep-2 different from the first depletion voltage Vdep-1 of the first group superjunction cells 10-1 and higher than the first depletion voltage Vdep-1, the first and second average dopant doses D11-2, D12-2 are equal and are higher than the (equal) first and second average dopant doses D11-1, D12-1 of the first group superjunction cells 10-1. Basically, the higher the first and second average doses D11-2, D12-2 of the second group superjunction cells 10-2 relative to the first and second average dopant doses D11-1, D12-1 of the first group superjunction cells 10-1 the higher the second depletion voltage Vdep-2 relative to the first depletion voltage Vdep-1.

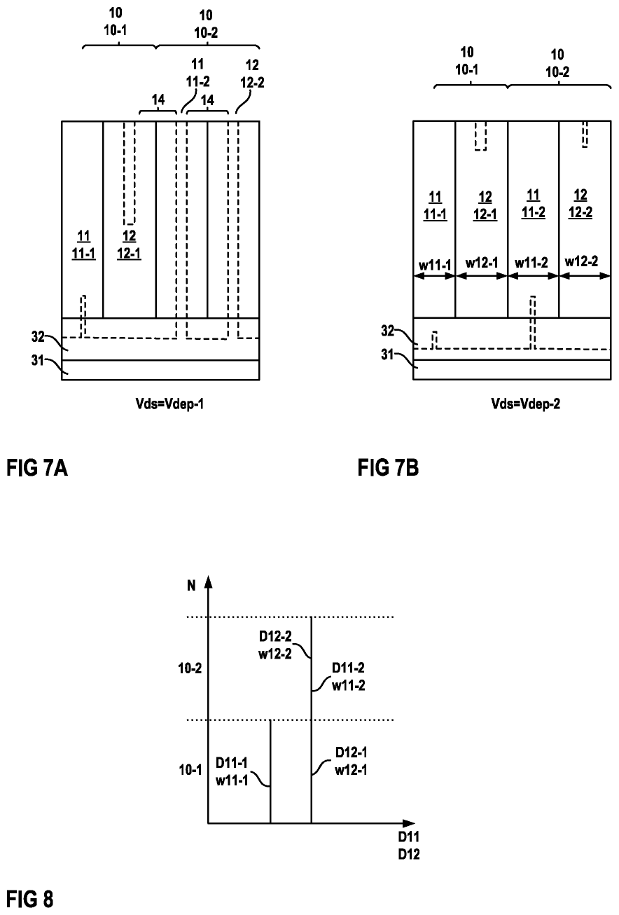

FIGS. 7A-7B schematically illustrate the operating principle of a superjunction transistor device with first group transistor cells 10-1 and second group transistor cells 10-2, wherein the first group transistor cells 10-1 are imbalanced and have a first depletion voltage Vdep-1 and the second group transistor cells 10-2 are balanced and have a second depletion voltage Vdep-2 higher than the first depletion voltage Vdep-1. Each of FIGS. 7A-7B shows a horizontal cross-sectional view of one first group superjunction cell 10-1 and one second group superjunction cell 10-2.

FIG. 7A illustrates an operating scenario in which the transistor device is in the off-state and the increasing drain-source voltage Vds has reached the first depletion voltage Vdep-1 so that the first region 11-1 of the imbalanced first transistor cell 10-1 is entirely depleted, while the second region 12-1 of the first transistor cell 11-1 and the first region 11-2 and the second region 12-2 of the balanced second superjunction cell 10-2 with the higher depletion voltage Vdep-2 have not yet been depleted. FIG. 7B illustrates the operating scenario in which the further increasing drain-source voltage Vds has reached the second depletion voltage Vdep-2, so that the first and second regions 11-2, 12-2 of the second superjunction cell 10-2 are depleted. At the second depletion voltage Vdep-2 the second region 12-1 of the first superjunction cell 10-1 may have been depleted or may not yet have been depleted.

FIG. 8 schematically illustrates examples of the average doses of the first and second regions of the first and second superjunction cells 10-1, 10-2 illustrated in FIGS. 7A-7B. Referring to FIG. 8, the first and second regions 11-1, 12-1 of the imbalanced first superjunction cell 10-1 have different first and second average doses D11-1, D12-1, wherein the first average dose D11-1 is lower than the second average dose D12-1, so that the first region 11-1 is entirely depleted before the second region 12-1 is entirely depleted as the drain-source voltage Vds increases. Furthermore, the first and second regions 11-2, 12-2 of the balanced second superjunction cell 10-2 have at least approximately the same average doses D11-2, D12-2.

The first depletion voltage Vdep-1 is lower than the second depletion voltage Vdep-2 because the first average dose D11-1 of the first superjunction cell 10-1 is lower than both the first average dose D11-2 and the second average dose D12-2 of the second superjunction cell 10-2. The second average dose D12-1 of the first superjunction cell 10-1 can be equal to (as illustrated), higher than, or lower than the first and second average doses D11-2, D12-2 of the second superjunction cell 10-2.

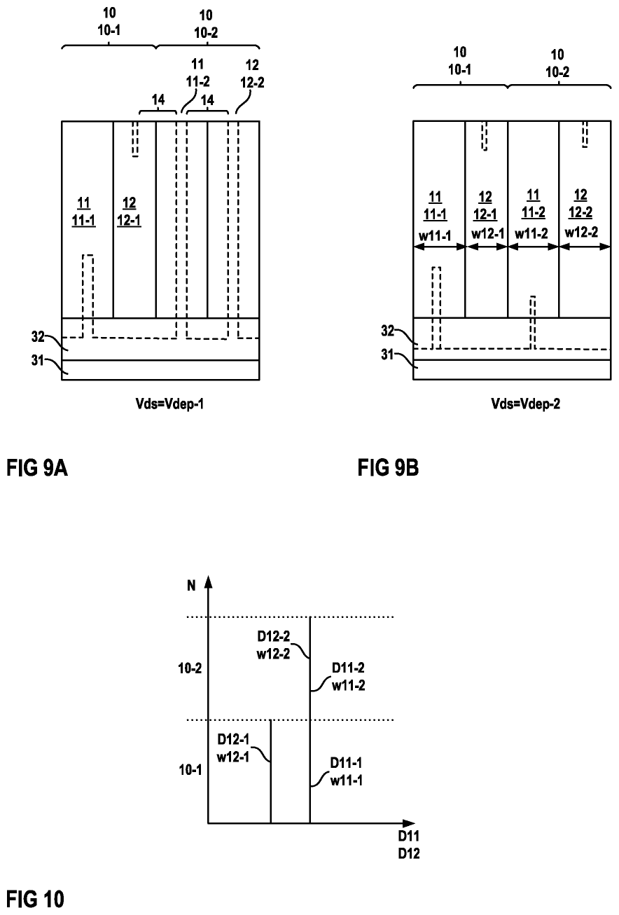

FIGS. 9A-9B schematically illustrate the operating principle of a superjunction transistor device with first group transistor cells 10-1 and second group transistor cells 10-2 according to another example, the first group transistor cells 10-1 being imbalanced and having a first depletion voltage Vdep-1 and the second group transistor cells 10-2 being balanced and having a second depletion voltage Vdep-2 higher than the first depletion voltage Vdep-1. Each of FIGS. 9A-9B shows a horizontal cross-sectional view of one first group superjunction cell 10-1 and one second group superjunction cell 10-2.

FIG. 9A illustrates an operating scenario in which the transistor device is in the off-state and the increasing drain-source voltage Vds has reached the first depletion voltage Vdep-1 so that the second region 12-1 of the imbalanced first transistor cell 10-1 is entirely depleted, while the first region 11-1 of the first transistor cell 11-1 and the first region 11-2 and the second region 12-2 of the balanced second superjunction cell with the higher depletion voltage Vdep-2 have not yet been depleted. FIG. 9B illustrates the operating scenario in which the further increasing drain-source voltage Vds has reached the second depletion voltage Vdep-2, so that the first and second regions 11-2, 12-2 of the second superjunction cell 10-2 are depleted. At the second depletion voltage Vdep-2 the first region 11-1 of the first superjunction cell 10-1 may have been depleted or may not yet have been depleted.

FIG. 10 schematically illustrates examples of the average doses of the first and second regions of the first and second superjunction cells 10-1, 10-2 illustrated in FIGS. 9A-9B. Referring to FIG. 10, the first and second regions 11-1, 12-1 of the imbalanced first superjunction cell 10-1 have different first and second average doses D11-1, D12-1, wherein the second average dose D12-1 is lower than the first average dose D11-1, so that the second region 12-1 is entirely depleted before the first region 11-1 is entirely depleted as the drain-source voltage Vds increases. Furthermore, the first and second regions 11-2, 12-2 of the balanced second superjunction cell 10-2 have at least approximately the same average doses D11-2, D12-2. The first depletion voltage Vdep-1 is lower than the second depletion voltage Vdep-2 because the second average dose D12-1 of the first superjunction cell 10-1 is lower than both the first average dose D11-2 and the second average dose D12-2 of the second superjunction cell 10-2. The first average dose D11-1 of the first superjunction cell 10-1 can be equal to (as illustrated), higher than, or lower than the first and second average doses D11-2, D12-2 of the second superjunction cell 10-2.

As can be seen from FIGS. 8 and 10, the lower depletion voltage Vdep-1 of the first superjunction cell 10-1 relative to the depletion voltage Vdep-2 of the second superjunction cell 10-2 can be obtained either by adjusting the first average dose 11-1 of the first superjunction cell 10-2 to be lower than each of the first and second average doses 11-2, 12-2 of the second superjunction cell 10-2, or by adjusting the second average dose 12-1 of the first superjunction cell 10-2 to be lower than each of the first and second average doses 11-2, 12-2 of the second superjunction cell 10-2. Basically, in several superjunction cells that one of the superjunction cells has the lowest depletion voltage that has the first region and/or the second region with the lowest average dose of the superjunction cells.

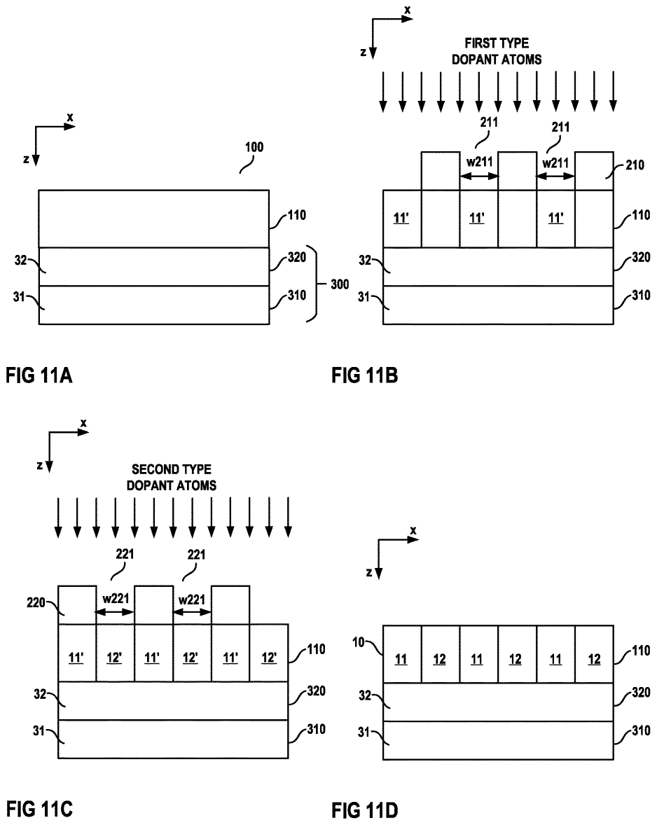

FIGS. 11A-11D illustrate one example of a method for forming the superjunction region 1 with the first and second regions 11, 12. Each of FIGS. 11A-11D illustrates a vertical cross-sectional view of one portion of the semiconductor body 100 during the manufacturing process.

Referring to FIG. 11A, the method includes forming a semiconductor layer 110 on top of a carrier 300. According to one example, the carrier 300 includes a semiconductor substrate 310 forming the drain region 31 in the finished transistor device, and a further semiconductor layer 320 formed on top of the substrate 310 and forming the buffer region 32 in the finished transistor device. According to one example, the further semiconductor layer 320 is epitaxial layer 320 and is in-situ doped during the epitaxial growth process in order to achieve the desired doping concentration of the buffer region 32. The semiconductor layer 110 formed on top of the carrier 300 is an epitaxial layer, for example.

It should be noted that the layer stack including the carrier 300 and the semiconductor layer 110 is a monocrystalline semiconductor arrangement forming a portion of the semiconductor body 100 of the finished transistor device. Due to the monocrystalline nature of the arrangement, there are no visible borders between the semiconductor layer 110 and the carrier 300 and between the substrate 310 and the further semiconductor layer 320 in the carrier.

Referring to FIG. 11B, the method further includes implanting first type dopant atoms through openings 211 of a first implantation mask 210 provided above the semiconductor layer 110 into the semiconductor layer 110 to form first implanted regions 11′. The openings 211 in the first implantation mask 210 are spaced apart from each other in the first lateral direction x and define the positions of the first regions 11 in the lateral direction x of the finished transistor device.

How deep the first type dopant atoms are implanted into the semiconductor layer 110 depends on the implantation energy. According to one example, the implantation process includes two or more implantation steps at different energies so that first type dopant atoms are implanted into different vertical depths of the semiconductor layer 110.

Referring to FIG. 11C, the method further includes implanting second type dopant atoms through openings 221 of a second implantation mask 220 provided above the semiconductor layer 110 into the semiconductor layer 110 to form second implanted regions 12′. The second implantation mask 220 is provided after removing the first implantation must 210. Furthermore, the openings 221 in the second implantation mask 220 are spaced apart from each other in the first lateral direction x and define the positions of the second regions 12 in the lateral direction x of the finished transistor device. Positions of the openings 221 in the second implantation mask 220 are offset in the first lateral direction x relative to positions of the openings 211 in the first implantation mask 210 in order to avoid the second implanted regions 12′ from overlapping the first implanted regions 11′.

According to one example, the implantation process for implanting the second type dopant atoms includes two or more implantation steps at different implantation energies, so that second type dopant atoms are implanted at different vertical depths of the semiconductor layer 110.

Referring to FIG. 11D, the method further includes an annealing process in which the implanted first type dopant atoms and second type dopant atoms are electrically activated to form the first regions 11 based on the first implanted regions 11′ and the second regions 12 based on the second implanted regions 12′. The annealing process can be a dedicated annealing process only used to electrically activate the first and second type dopant atoms included in the first and second implanted regions 11′, 12′. According to another example, annealing processes used for forming the transistor cells 2 are used to electrically activate the dopant atoms implanted in the processes illustrated in FIGS. 11B and 11C.

As explained above, the first and second regions 11, 12 can be elongated in the second lateral direction y. According to one example, the first openings 211 in the first implantation must 210 and the second openings 221 in the second implantation mask 220 are elongated in the second lateral direction y in order to form elongated first and second implanted regions 11′, 12′ in the implantation processes and form elongated first and second regions 11, 12 based on the elongated first and second implanted regions 11′, 12′ in the annealing process.

Referring to the above, the voltage blocking capability of the transistor device is substantially dependent on the dimension of the superjunction region 1 in the vertical direction z. According to the example illustrated in FIGS. 11A-11D, the first and second implanted regions 11′ and 12′ may be formed in only one semiconductor layer 110 formed on top of the carrier 300.

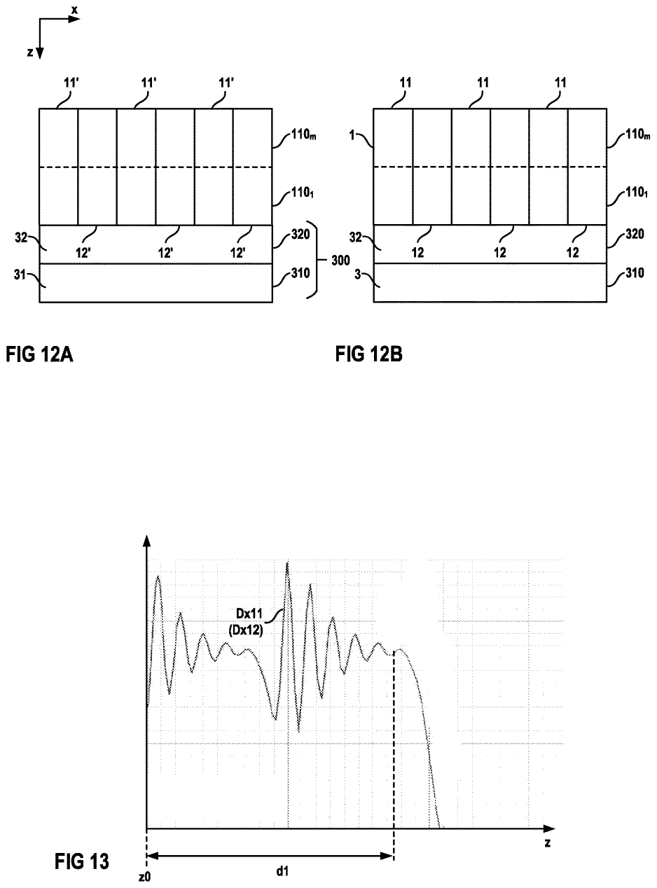

According to another example illustrated in FIGS. 12A-12B, several semiconductor layers 110₁, 110ₘ are formed one above the other on top of the carrier 300 and first and second implanted regions 11′, 12′ are formed in each of the semiconductor layers 110₁, 110ₘ before forming a next one of the several semiconductor layers 110₁, 110ₘ. The semiconductor layers 110₁, 110ₘ are epitaxial layers, for example, so that this type of process is sometimes referred to as multi-epi-multi-implant (MEMI) process.

FIG. 12A illustrates a layer stack with the carrier 300 and several semiconductor layers 110₁, 110ₘ formed one above the other on top of the carrier 300 and each having first and second implanted regions 11′, 12′ formed therein. Just for the purpose of illustration, the several semiconductor layers include two semiconductor layers 110₁, 110ₘ in the example illustrated in FIG. 12A. Of course, more than two semiconductor layers can be formed one above the other on top of the carrier 300.

The method explained with reference to FIGS. 11A-11C can be used to form the first and second implanted regions 11′, 12′ in each of the several layers 110₁, 110ₘ.

FIG. 12B shows the layer stack with the carrier 300 and the several semiconductor layers 110₁, 110ₘ after the annealing process that electrically activates the first and second type dopant atoms.

Referring to FIG. 12A lateral positions of the first implanted regions 11′ in the semiconductor layers 221 are selected such that the plurality of first implanted regions 11′ form a plurality of groups, each group including one first implanted region 11′ in each semiconductor layer 110₁, 110ₘ, and the first implanted regions 11 of each group being arranged one above the other in the vertical direction z. In a similar way, lateral positions of the second implanted regions 12′ in the semiconductor layers 110₁, 110ₘ are selected such that the plurality of second implanted regions 12′ form a plurality of groups, each group including one second implanted region 12′ in each semiconductor layer 110₁, 110ₘ, and the second implanted regions 12′ of each group being arranged one above the other in the vertical direction z. In this way, contiguous (pillar-shaped) first and second regions 11, 12 are formed based on the annealing process.

It should be noted that in a transistor device based on a SiC semiconductor body 100 there is essentially no diffusion of the dopant atoms in the annealing process, so that the implantation processes essentially define the positions and the dimensions of the first and second regions 11, 12 in the vertical direction z as well as in the lateral directions x, y.

Referring to FIGS. 11B and 11C, the first openings 211 in the first implantation mask 210 have a first width w211 and the second openings 221 in the second implantation mask have a second with w221. The widths w211, w221 are the dimensions of the openings 211, 221 in the first lateral direction x. In particular in a transistor device based on an SiC semiconductor body 100, it can be shown that the first average dose of a first region 11 is directly proportional to the width of the opening in the first implantation mask 210 used to form the respective first region 11 and that the second average dose of a second region 12 is directly proportional to the width of the opening in the second implantation mask 220 used to form the respective second region 12.

In an example in which several semiconductor layers are formed on top of the carrier 300, each first region 11 is formed to have the same width in each of the semiconductor layers and each second region 12 is formed to have the same width in each of the semiconductor layers.

In FIGS. 5A-10, w11 added by an identifier (such as −1, −2) denotes the width of the respective first region 11 and w12 added by an identifier denotes the width of the respective second region 12, where it is assumed that the respective average dose D11 is proportional to the respective first width w11 and the second average dose D12 is proportional to the respective second width w12.

As explained with reference to FIGS. 12A-12B, two or more semiconductor layers may be formed one above the other and first type dopant atoms and second type dopant atoms may be implanted into each of the semiconductor layers at different implantation energies. FIG. 13 schematically illustrates one example of the lateral dopant dose Dx11 in a first region 11 and/or the lateral dopant dose Dx12 in a second region 12 of one superjunction cell 10 over the entire superjunction region 1 in the vertical direction z. The superjunction cell 10 is balanced, for example, when the first and second lateral dopant doses Dx11, Dx12 have the same profile.

As can be seen from FIG. 13, the lateral dopant dose varies in the vertical direction z. This is due to the implantation process. At each implantation energy a peak of the concentration of the respective dopant atoms occurs at a position defined by the implantation energy, wherein the dopant atoms implanted at one implantation energy are distributed around the peak. Basically, the lower the implantation energy, the more pronounced the peak and the lower the distribution around the peak, and the higher the implantation energy, the less pronounced the peak and the higher the distribution around the peak.

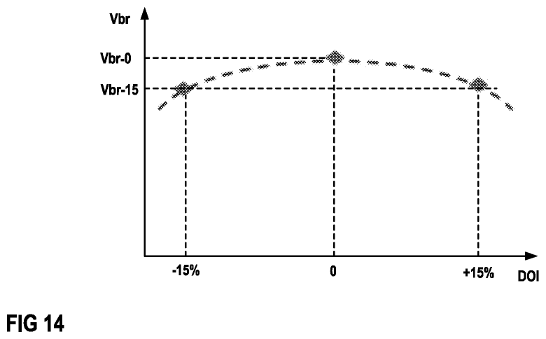

As explained above, the superjunction cells 10 can be balanced or imbalanced. Implementing the transistor device with one or more groups of imbalanced superjunction cells 10 may reduce the voltage blocking capability of the transistor device as compared to implementing the transistor device with balanced superjunction cells 10, only. The reduction of the voltage blocking capability as associated with imbalanced superjunction cells 10 is explained with reference to FIG. 14 in the following.

FIG. 14 illustrates the voltage blocking capability Vbr of a superjunction transistor device dependent of a degree of imbalance DOI of the superjunction cells 10 included in the transistor device. The degree of imbalance DOI is zero when the superjunction cells 10 are balanced. When the superjunction cells 10 are balanced, the superjunction transistor device has the highest breakdown voltage Vbr-0.

According to one example, the degree of imbalance DOI is positive when the second average dose D12, which defines the amount of second type dopant atoms in the second region 12, is higher than the first average dose D11, which defines the amount of first type dopant atoms in the first region 11, and the degree of imbalance DOI is negative when the second average dose D12, which defines the amount of first type dopant atoms in the first region 11, is lower than the first average dose D11. According to one example, the degree of imbalances of a superjunction cell 10 is given by

$$DOI = \frac{( D 12 - D 11 )}{Dref} , \qquad ( 1 )$$

where D11 denotes the average dose of the first region 11, D12 denotes the average dose of the second region 12, and Dref denotes a reference average dose.

As can be seen from FIG. 14, the breakdown voltage decreases as the degree of imbalance DOI increases both towards positive values and negative values. Furthermore, the decreasing breakdown voltage is essentially symmetric relative to the highest breakdown voltage Vbr-0 achieved when the superjunction cells are balanced.

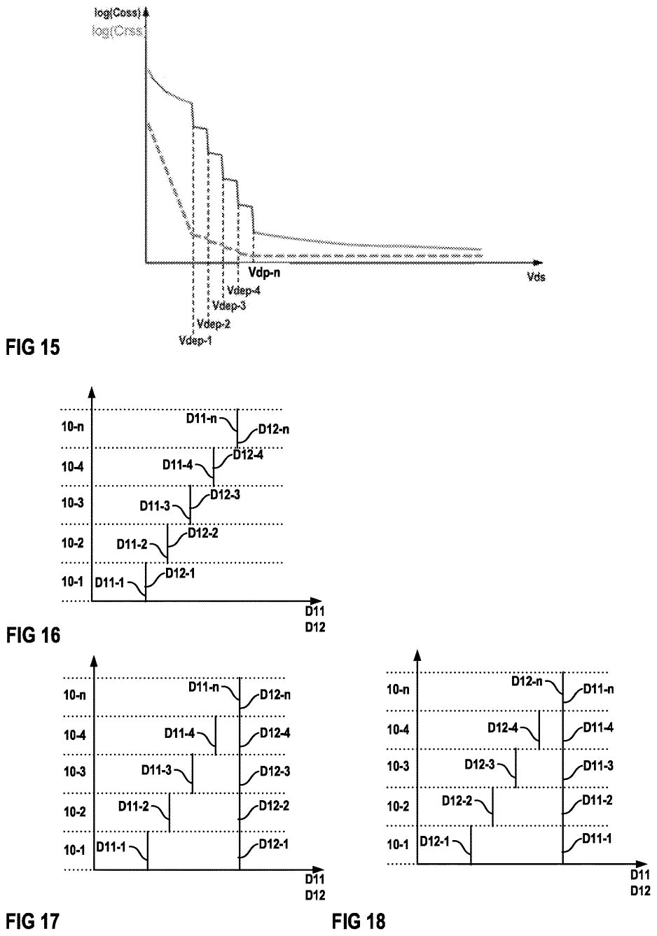

FIG. 15 illustrates the dependency of the output capacitance Coss and the feedback capacitance Crss in a superjunction transistor device with more than two different groups of superjunction cells. Just for the purpose of illustration, the superjunction transistor device includes five different groups of superjunction cells, the superjunction cells of each of the five groups having a depletion voltage Vdep-1, Vdep-2, Vdep-3, Vdep-4, Vdep-n, the depletion voltages Vdep-1, Vdep-2, Vdep-3, Vdep-4, Vdep-n being different. In the transistor device according to FIG. 15, due to the higher number of different groups of superjunction cells, the decrease of the output capacitance Coss and the feedback capacitance Crss is smoother than in the transistor device illustrated in FIG. 4, which includes only two different groups of superjunction cells.

FIGS. 16-22 illustrate various examples of how the different depletion voltages Vdep-1 to Vdep-n can be achieved. In each of FIGS. 15-22 D11-1, D11-2, D11-3, D11-4, D11-n denote the average doses of the first regions 11 in the different groups of superjunction cells 10-1, 10-2, 10-3, 10-4, 10-n and D11-1, D12-2, D12-3, D12-4, D12-n denote the average doses of the second regions 12 in the different groups of superjunction cells 10-1, 10-2, 10-3, 10-4, 10-n.

According to one example illustrated in FIG. 16, the superjunction cells 10-1, 10-2, 10-3, 10-4, 10-n are balanced, so that the first and second average doses in the superjunction cells of each group 10-1, 10-2, 10-3, 10-4, 10-n are equal, but the individual superjunction cells 10-1, 10-2, 10-3, 10-4, 10-n have different average doses. The group of superjunction cells with the lowest first and second doses, which are average doses D11-1, D12-1 in the example illustrated in FIG. 16, has the lowest depletion voltage Vdep-1, and the group of superjunction cells with the highest first and second doses, which are doses D11-n, D12-n in the example illustrated in FIG. 16 has the highest depletion voltage Vdep-n.

FIG. 17-22 illustrate the doping situation in various examples of transistor devices that each includes imbalanced superjunction regions. In the examples illustrated in FIG. 17-19 the superjunction cells of one group 10-n are balanced. This, however, is only an example. It is also possible to implement the superjunction with imbalanced superjunction cells, only.

In the example illustrated in FIG. 17, groups with imbalanced transistor cells 10-1 to 10-4 have a positive degree of imbalance as in each of these groups the respective second average dose D12-1 to D12-4 is higher than the respective first average dose D11-1 to D11-4. According to one example, the second average doses D12-1 to D12-n are equal.

In the example illustrated in FIG. 18, groups with imbalanced transistor cells 10-1 to 10-4 have a negative degree of imbalance as in each of these groups the respective second average dose D12-1 to D12-4 is lower than the respective first average dose D11-1 to D11-4. According to one example, the first average doses D12-1 to D12-n are equal.

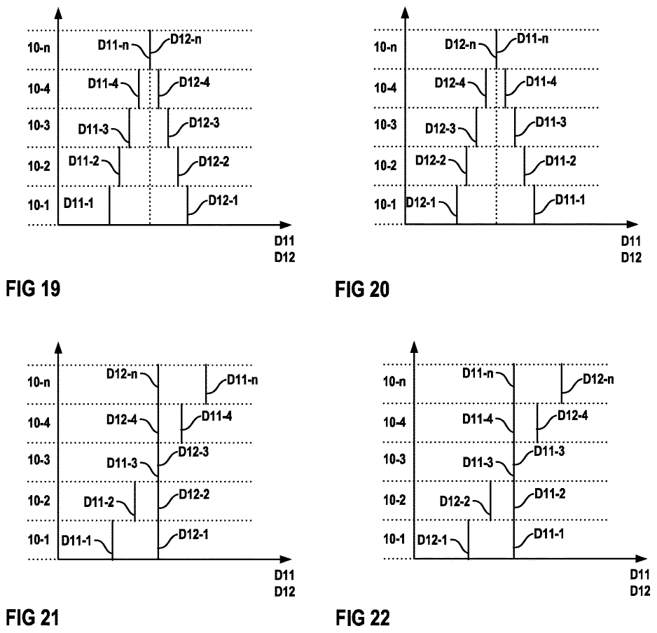

The example illustrated in FIG. 19 is based on the example illustrated in FIG. 17 and is different from the example illustrated in FIG. 17 in that the second average doses D12-1 to D12-n are different from each other and are adjusted in such a way that the lower the associated first average dose D11-1 to D11-n the higher the respective second average dose D12-1 to D12-n.

The example illustrated in FIG. 20 is based on the example illustrated in FIG. 17 and is different from the example illustrated in FIG. 17 in that the first average doses D11-1 to D11-n are different from each other and are adjusted in such a way that the lower the associated second average dose D12-1 to D12-n the higher the respective first average dose D11-1 to D11-n.

Referring to the above, the first and second average doses D11, D12 of a superjunction cell 10 can be proportional to a width w11, w12 of the first and second regions 11, 12 of the superjunction cell 10. According to one example, in superjunction transistor devices of the type illustrated in FIGS. 19 and 20, overall average doses of the individual superjunction cells 10-1 to 10-n are essentially equal, so that the individual superjunction cells 10-1 to 10-n have essentially the same width. The overall dose of a superjunction cell 10 is given by the first average dose D11 plus the second average dose D12.

FIGS. 21-22 illustrate the doping situation in transistor devices that include groups of imbalanced transistor cells, with some of the groups having a positive degree of imbalance and other groups having a negative degree of imbalance.

In the example illustrated in FIG. 21, groups 10-1, 10-2 have a positive degree of imbalance DOI as the second average doses D12-1, D12-2 of these groups 10-1, 10-2 are higher than the respective first average doses D11-1, D11-2, and groups 10-4, 10-n have a negative degree of imbalance as the second average doses D12-4, D12-n of these groups 10-4, 10-n are lower than the respective first average doses D11-4, D11-n. The further group 10-3 is balanced as the first and second average doses D11-3, D12-3 are equal.

In the example illustrated in FIG. 22, groups 10-1, 10-2 have a negative degree of imbalance DOI as the second average doses D12-1, D12-2 of these groups 10-1, 10-2 are lower than the respective first average doses D11-1, D11-2 and groups 10-4, 10-n have a positive degree of imbalance as the second average doses D12-4, D12-n of these groups 10-4, 10-n are higher than the respective first average doses D11-4, D11-n. The further group 10-3 is balanced as the first and second average doses D11-3, D12-3 are equal.

In each of the groups of superjunction cells 10-1 to 10-n a lower average dose is that one of the first and second average doses D11, D12 that is lower than (or equal to) the other one of the first and second average doses D11, D12. Basically, the group of superjunction cells 10-1, 10-n having the lowest one of the lower average doses has the lowest depletion voltage Vdep-1. In the examples illustrated in FIGS. 17-22 it is group 10-1 that has the lowest one of the lower average doses and has the lowest depletion voltage Vdep-1. Furthermore, the group of superjunction cells having the highest one of the lower average doses has the highest depletion voltage Vdep-n. In the examples illustrated in FIGS. 17-22 it is group 10-n that has the highest one of the lower average doses and the highest depletion voltage Vdep-n.

In the examples illustrated in FIGS. 17-20 that include one group 10-n of balanced superjunction cells, the average first and second doses D11-n, D12-n of the balanced superjunction cells may correspond to the reference average dose Dref explained with reference to equation (1).

According to one example, in a transistor device with imbalanced superjunction cells, the magnitude of the degree of imbalance is not higher than 5%, not higher than 10%, or not higher than 15%. The superjunction transistor device can be implemented only with imbalanced superjunction cells having a positive degree of imbalance DOI, only with imbalanced superjunction cells having a negative degree of imbalance DOI, or with superjunction cells having a positive degree of imbalance DOI and other superjunction cells having a negative degree of imbalance DOI. In each example, the transistor device may further include balanced superjunction cells.

Referring to the above, the transistor device may include groups of superjunction cells with different depletion voltages. According to one example, the superjunction region 1 is divided in several areas wherein in each of these areas the superjunction cells 10 of one group are implemented.

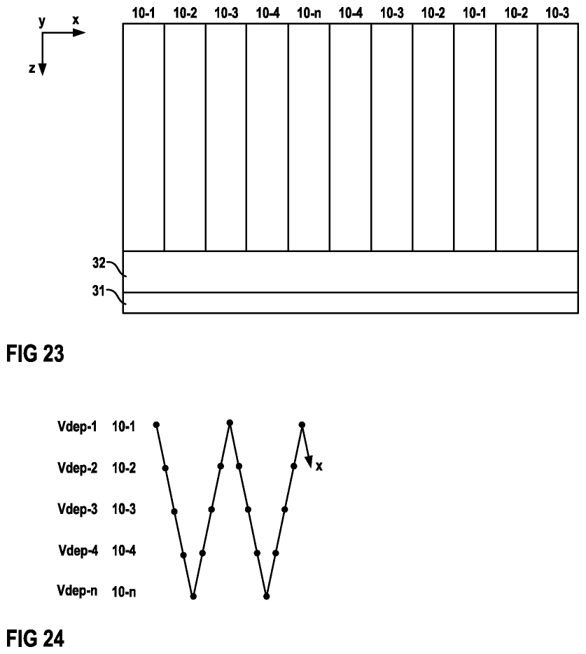

According to another example illustrated in FIG. 23, superjunction cells 10-1 to 10-n of different groups are arranged in interleaved fashion so that the depletion voltage increases or decreases from superjunction cell to superjunction cell. In the example illustrated in FIGS. 23 and 24, superjunction cells of group 10-1 have the lowest depletion voltage and superjunction cells of group 10-n have the highest depletion voltage. In the example illustrated in FIG. 23, the superjunction cells are arranged alternately in ascending and descending order, wherein as ascending order includes that the depletion voltage increases from superjunction cell to super junction cell and descending order includes that the depletion voltage decreases from superjunction cell to superjunction cell. The latter is schematically illustrated in FIG. 24 that shows in which order the superjunction cells are arranged and shows the as associated depletion voltage, with Vdep-1 being the lowest depletion voltage and Vdep-n being the highest depletion voltage.

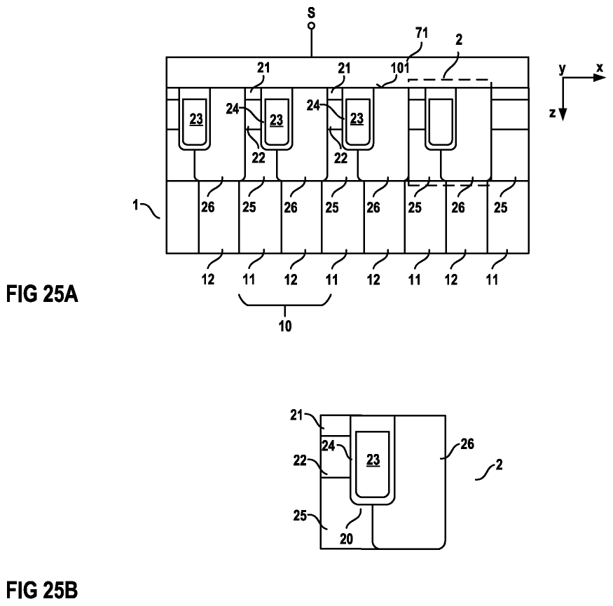

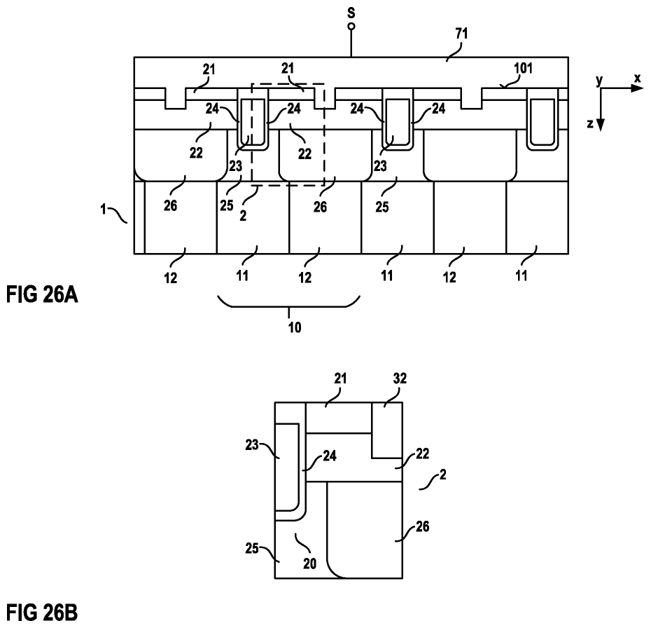

FIGS. 25A and 26A illustrate transistor cells 2 according to different examples, FIG. 25B shows one of the transistor cells 2 illustrated in FIG. 25A in detail, and FIG. 26B shows one of the transistor cells 2 illustrated in FIG. 26A in detail.

Referring to FIGS. 25A-26B, each transistor cell 2 includes a source region 21 of the first doping type, a body region 22 of the second doping type (complementary to the first doping type), and a gate electrode 23. The gate electrode 23 is adjacent to the body region 22, is dielectrically insulated from the body region 22 by a gate dielectric 24 and is arranged in a gate trench 20 extending from the first surface 101 of the semiconductor body 100 into the semiconductor body 100. The gate trenches 20 with the gate electrodes 23 are spaced apart from each other in the first lateral direction x and may be elongated in the second lateral direction y.

In the example illustrated in FIGS. 25A-25B, the body region 22 is adjacent to the gate trench 20 on only one side. On the opposite side of the gate trench 20 a connection region 26 of the second doping type extends from the first surface 101 down to the second region 12 of a respective superjunction cell 10.

In the example illustrated in FIGS. 26A-26B, source and body regions 21, 22 of two neighboring transistor cells 2 are arranged in a mesa region between neighboring gate trenches 20. In this example, the body regions 22 of the two neighboring transistor cells 2 may be formed by one contiguous doped region of the second doping type. Furthermore, two (other) neighboring transistor cells may share the gate electrode 23. That is, the gate electrodes 23 of two neighboring transistor cells may be formed by one contiguous electrode arranged in one gate trench 20. In this example, a connection region 26 of the second doping type extends from the body region 22 down to the second region 12 of a respective superjunction cell 10.

Referring to the above, the source regions 21 of the transistor cells 2 are connected to the source node S of the transistor device. The transistor device may include a source electrode 71, which either forms the source node S or is connected to the source node S.

The source electrode 71 is formed above the first surface 101 and is electrically connected to the source and body regions 21, 22 of the transistor cells 20. Connections that connect the source region 71 to the body regions 21, 22 may include vias that extend from the source electrode 72 through the source regions 21 to the body regions 22.

The gate electrodes 23 are connected to the gate node G. Connections between the gate electrodes 23 and the gate node G are not illustrated in FIGS. 25A and 26A. In a conventional way, the gate electrodes 23 may be connected to a gate runner at their longitudinal ends, the gate runner being formed above the first surface 101 and spaced apart from the source electrode 71. Furthermore, the gate runner is connected to a gate pad also formed above the first surface 101 and spaced apart from the source electrode 71. The gate pad is connected to the gate node G or forms the gate node. Connecting elongated gate electrodes, such as gate electrodes 23 according to FIGS. 25A and 25B, to a gate node in this way is a commonly known practice in vertical transistor device is, so that no further explanation is required in this regard.

Referring to the above, the second regions 12 of the first superjunction region 1 are coupled to the source node S. In the example illustrated in FIG. 25A, each of the second regions 12 is coupled to the source node S via the respective connection region 26 and in the example illustrated in FIG. 26A, each of the second regions 12 is connected to the source node via the connection region 26 and the body region 22.

Referring to the above, the transistor device can be operated in the on-state or the off-state. The transistor device is in the on-state when the gate-source voltage is such that a conducting channel is generated by the gate electrode 23 in the body region 22 along the gate dielectric. The transistor device is in the off-state when the conducting channel is interrupted. To enable a current flow from the source node S to the drain node D when the transistor device is in the on-state, that portion of the body region 22 in which the conducting channel is generated either adjoins a respective first region 11 or, as illustrated in FIGS. 25A and 26A is connected to the first region 11 by a current spreading region 25 of the first doping type. In this way, in the on-state, charge carriers can move from the source regions 21 along the conducting channels in the body regions 22, the first regions 11 of the first superjunction region 1 and the buffer region 32 to the drain region 31 (the buffer region 32 and the drain regions 31 not illustrated in FIGS. 25A-25B).

In the circuit symbols of the transistor cells 2 illustrated in FIG. 1, the electronic switch represents the conducting channel along the gate dielectric 24 in the body region 22. The diode in the circuit symbol represents a diode formed by a PN junction between the first region 11 (drift region) and the body region 22, which is usually referred to as body diode.

In the examples illustrated in FIGS. 25A and 26A, the gate trenches 20 with the gate electrodes 23 are spaced apart from each other in the first lateral direction x and longitudinally extend in the second lateral direction y. In this example, the gate trenches 20 longitudinally extend in the same direction in which the first and second regions 11, 12 longitudinally extend. According to another example (not illustrated) longitudinal directions of the gate trenches 20 with the gate electrodes 23 are perpendicular to longitudinal directions of the first and second regions 11, 12.

According to one example, the transistor device is an N-type transistor device. In this example, the regions of the first doping type, such as the drain and buffer regions 51, 52, the first and third regions 11, 13, the first termination region 31 and the source regions 21 are N-type regions and the regions of the second doping type, such as the second and fourth regions 12, 22 and the second termination region 32 are P-type regions. An N-type transistor device is in the forward biased mode when a positive voltage is applied between the drain node D and the source node S.

According to another example, the transistor device is a P-type transistor device. In this example, the regions of the first doping type are P-type regions and the regions of the second doping type are N-type regions.

It should be noted that implementing the transistor cells 2 with gate electrodes 23 arranged in gate trenches 20, as illustrated in FIGS. 25A-26B, is only an example. According to another example (not illustrated) the gate electrodes are planar gate electrodes arranged above the first surface 101.

According to one example, the cell field including the transistor cells 2 has a pitch, the pitch being the center-to-center distance between adjacent gate trenches 20. The superjunction region 1 also has a pitch, the pitch being the center-to-center distance between adjacent first regions 11 or between adjacent second regions, or the pitch being the dimension of one superjunction cell 10 in the first lateral direction x.

According to one example, the cell field including the transistor cells 2 and the superjunction region 1 have the same pitch. This can be achieved by implementing the superjunction cells 10 such that each superjunction cell 10 has the same width in the first lateral direction. This can be achieved by implementing the superjunction region 1 in accordance with the examples illustrated in FIGS. 19 and 20.

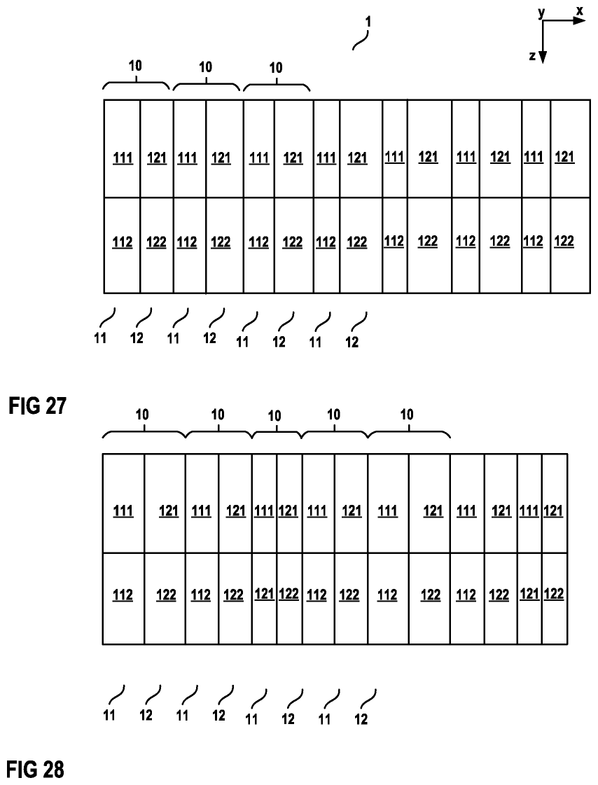

FIGS. 27 and 28 illustrate superjunction regions 1 according to further examples. In these examples, each first region 11 has at least two different sections, a first section 111 and a second section 112, arranged adjacent in the vertical direction z, and each second region 12 has at least two different sections, a first section 121 and a second section 122, arranged adjacent in the vertical direction z. The first and second sections 111, 112 of the first region 11 have different average doses, and the first and second sections of the second region 12 have different average doses. According to one example, the average dose of the first section 111 of the first region 11 is lower than the average dose of the second section 112 of the first region 11, and the average dose of the first section 121 of the second region 12 is higher than the average dose of the second section 122 of the second region 12. The average dose of the first region 11 is defined by the average doses of the first and second sections 111, 112 of the first region 11, and the average dose of the second region 12 is defined by the average doses of the first and second sections 121, 122.

A first section 111 of a first region 11 and an adjoining first section 121 of a second region 12 of a superjunction cell 10 form a first section of the superjunction cell 10, and a second section 112 of a first region 11 and an adjoining second section 122 of a second region 12 form a second section of the superjunction cell 10.

According to one example, the dimension of the first sections 111, 121 of the first and second regions 11, 12 is between 40% and 60% of an overall dimension of the superjunction region 1 in the current flow direction.

According to one example, the superjunction cells 10 are implemented such that (a) there is an imbalance of the average lateral dopant doses in the first sections 111, 121 of the first and second regions 11, 12 of a superjunction cell 10 such that there is an excess of one of first dopant atoms or second type dopant atoms in the first section of the superjunction cell 10; and (b) there is an imbalance of the average lateral dopant doses in the second sections 112, 122 of the first and second regions 11, 12 of a superjunction cell 10 such that there is an excess of the other one of first dopant atoms or second type dopant atoms in the first section of the superjunction cell 10. Implementing the transistor device in this way makes the transistor device less susceptible to variations in the voltage blocking capability that may result from variations in the implantation process used to form the superjunction region 1.

According to one example, there is an excess of second type dopant atoms in the first sections of the superjunction cells 10 and an excess of first type dopant atoms in the second sections of the superjunction cells 10. This can be achieved by (i) implementing the first sections 112 of the second regions 12 to have a higher average lateral dopant dose than the first sections 111 of the first regions 11; and (ii) implementing the second sections 121 of the first regions 11 to have a higher average lateral dopant dose than the second sections 122 of the second regions 12.

In each case, the superjunction region 1 has superjunction cells 10 with different depletion voltages. This can be achieved by implementing the superjunction region 1 with at least two different types (groups) of superjunction cells 10, wherein the superjunction cells 10 of different groups are different from each other with regard to the average lateral dopant dose of at least one of the first and second regions 11, 12.

According to the example illustrated in FIG. 27, the superjunction cells 10 of the different groups have essentially the same width, so that in the superjunction cells 10 of the same group the first and second regions 11, 12 may have different widths.

According to another example illustrated in FIG. 28, in the superjunction cells 10 of the different groups the first and second regions 11, 12 essentially have the same width, so that the superjunction cells of the different groups have different widths.

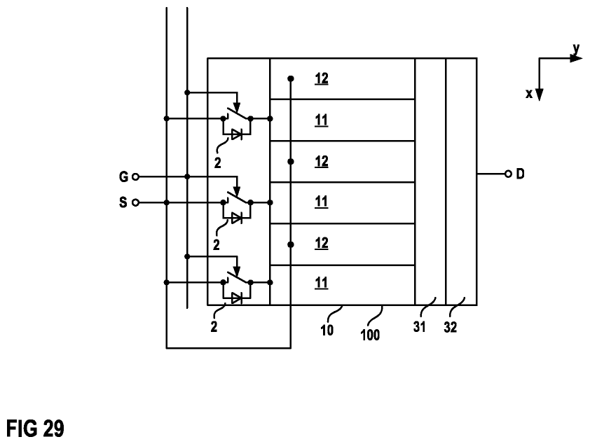

The superjunction transistor device explained herein before is a vertical transistor device. That is, a current flow direction equals the vertical direction z of the semiconductor body 100. Implementing the superjunction region 1 with superjunction cells 10 having different depletion voltages, however, is not restricted to be used in a vertical transistor device. Instead, everything explained herein before applies to a lateral transistor device accordingly. One example of a lateral transistor device is schematically illustrated in FIG. 29.

In the lateral transistor device according to FIG. 29, the transistor cells 2 and the drain and buffer region 31, 32 are spaced apart from each other in the second lateral direction y, while the first and second regions 11, 12 of the superjunction region 1 are arranged alternately in the first lateral direction x. The current flow direction is the second lateral direction y in this example.

Some of the examples explained above are briefly summarized in the following with reference to numbered examples.

Example 1. A transistor device, including: a drain node and a source node; a superjunction region arranged in a semiconductor body and including a plurality of superjunction cells each including a first region of a first doping type and a second region of a second doping type complementary to the first doping type; and a plurality of transistor cells; wherein the first and second regions are arranged alternately in a first direction of the semiconductor body; wherein the second regions are coupled to the source node; wherein each of the first regions is coupled to the source node via at least one of the transistor cells and is coupled to the drain node; and wherein the superjunction cells include at least two different groups of superjunction cells that are different from each other in terms of the depletion voltage of the respective superjunction cells.

Example 2. The transistor device of example 1, wherein the depletion voltage of a superjunction cell is the voltage applied between the drain and source nodes necessary to deplete at least 80% of at least one of the first and second regions of the superjunction cell.

Example 3. The transistor device of example 1 or 2, wherein each superjunction cell has a first average dopant dose and a second average dopant dose, and wherein the superjunction cells of the at least two different groups are different from each other in terms of at least one of the first and second average dopant doses.

Example 4. The transistor device of example 3, wherein the first average dopant dose is the average of a lateral dopant dose of the first region of the superjunction cell over a first section of the superjunction region, the first section extending in a current flow direction of the semiconductor body, and wherein the second average dose is the average of a lateral dopant dose of the second region of the superjunction cell over the first section.

Example 5. The transistor device of examples 3 or 4, wherein the superjunction cells of the two different groups of superjunction cells are different from each other in terms of at least one of the first average dopant dose or the second average dopant dose.

Example 6. The transistor device of any one of examples 1 to 5, wherein the superjunction cells of at least one of the two groups are balanced such that the first average dopant dose at least approximately equals the second average dopant dose.

Example 7. The transistor device of example 2, wherein the superjunction cells of each of the two groups are balanced.

Example 8. The transistor device of any one of examples 1 to 6, wherein superjunction cells in at least one of the at least two groups of superjunction cells are different from each other in terms of either the first average dopant dose or the second average dopant dose, and wherein, in each of the at least two groups of superjunction cells, either the first average dopant dose or the second average dopant dose is at least approximately equal.

Example 9. The transistor device of any one of examples 1 to 6, wherein the at least two groups of superjunction cells are different from each other in terms of both the first average dopant dose and the second average dopant dose.

Example 10. The transistor device of any one of examples 1 to 6, wherein each first region of each superjunction cell has a first section and a second section, wherein each second region of each superjunction cell has a first section and a second section, wherein the first section of the first region is adjacent to the first section of the second region, wherein the second section of the first region is adjacent to the second section of the second region, wherein, in the first region, an average dopant dose of the first section is different from an average dopant dose of the second section, and wherein, in the second region, an average dopant dose of the first section is different from an average dopant dose of the second section.

Example 11. The transistor device of example 10, wherein, in the first region, the average dopant dose of the first section is lower than an average dopant dose of the second section, and wherein in the second region, the average dopant dose of the first section is higher than an average dopant dose of the second section.

Example 12. The transistor device of example 10 or 11, wherein, the average dopant dose of the first section of the first region is lower than the average dopant dose of the first section of the second region; and second section, and wherein, the average dopant dose of the second section of the first region is higher than the average dopant dose of the second section of the second region.

Example 13. The transistor device of any one of examples 9 to 12, wherein each superjunction cell has a width in the first direction; and wherein the superjunction cells at least approximately have the same width.

Example 14. The transistor device of any one of examples 1 to 13, wherein the semiconductor body includes monocrystalline silicon carbide.

Example 15. The transistor device of any one of examples 1 to 14, wherein each transistor cell includes: a source region of the first doping type; a body region of the second doping type; and a gate electrode arranged adjacent to the body region and dielectrically insulated from the body region by a gate dielectric, wherein the body region is arranged between the source region and the current spreading region.

Example 16. The transistor device of example 13, wherein each transistor cell further includes a current spreading region adjoining at least one first region.

Example 17. The transistor device of example 15 or 16, wherein the gate electrodes of the transistor cells each extends longitudinally in a second direction perpendicular to the first direction, wherein the superjunction cells each extend longitudinally in a third direction, and wherein the second direction at least approximately equals the third direction.

Example 18. The transistor device of example 15 or 16, wherein the gate electrodes of the transistor cells each extends longitudinally in a second direction perpendicular to the first direction, wherein the superjunction cells each extend longitudinally in a third direction, and wherein the second direction is at least approximately perpendicular to the third direction.

Example 19. The transistor device of any one of examples 1 to 18, wherein the transistor device has a current flow direction; and wherein the current flow direction corresponds to a vertical direction of the semiconductor body.

Example 20. The transistor device of any one of examples 1 to 18, wherein the transistor device has a current flow direction; and wherein the current flow direction corresponds to a lateral direction of the semiconductor body.

Example 21. A transistor device, including: a drain node and a source node; a superjunction region arranged in a semiconductor body and including a plurality of superjunction cells each including a first region of a first doping type and a second region of a second doping type complementary to the first doping type; and a plurality of transistor cells; wherein the first and second regions are arranged alternately in a first direction of the semiconductor body; wherein the second regions are coupled to the source node; wherein each of the first regions is coupled to the source node via at least one of the transistor cells and is coupled to the drain node; wherein the superjunction cells include at least two different groups of superjunction cells; wherein each superjunction cell has a first average dopant dose and a second average dopant dose; and wherein the superjunction cells of the at least two different groups are different from each other in terms of at least one of the first and second average dopant doses.

1. A transistor device, comprising:
a drain node and a source node;
a superjunction region arranged in a semiconductor body and comprising a plurality of superjunction cells each comprising a first region of a first doping type and a second region of a second doping type complementary to the first doping type; and
a plurality of transistor cells;
wherein the first and second regions are arranged alternately in a first direction of the semiconductor body;
wherein the second regions are coupled to the source node;
wherein each of the first regions is coupled to the source node via at least one of the transistor cells and is coupled to the drain node; and
wherein the superjunction cells comprise at least two different groups of superjunction cells that are different from each other in terms of the depletion voltage of the respective superjunction cells.

2. The transistor device of claim 1,
wherein the depletion voltage of a superjunction cell is the voltage applied between the drain and source nodes necessary to deplete at least 80% of at least one of the first and second regions of the superjunction cell.

3. The transistor device of claim 1,
wherein each superjunction cell has a first average dopant dose and a second average dopant dose, and
wherein the superjunction cells of the at least two different groups are different from each other in terms of at least one of the first and second average dopant doses.

4. The transistor device of claim 3,
wherein the first average dopant dose is the average of a lateral dopant dose of the first region of the superjunction cell over a first section of the superjunction region, the first section extending in a current flow direction of the semiconductor body, and
wherein the second average dose is the average of a lateral dopant dose of the second region of the superjunction cell over the first section.

5. The transistor device of claim 3,
wherein the superjunction cells of the two different groups of superjunction cells are different from each other in terms of at least one of the first average dopant dose or the second average dopant dose.

6. The transistor device of claim 3,
wherein the superjunction cells of at least one of the two groups are balanced such that the first average dopant dose at least approximately equals the second average dopant dose.

7. The transistor device of claim 2,
wherein the superjunction cells (10) of each of the two groups (10-1-10-n) are balanced.

8. The transistor device of claim 3,
wherein superjunction cells in at least one of the at least two groups of superjunction cells are different from each other in terms of either the first average dopant dose or the second average dopant dose, and
wherein, in each of the at least two groups of superjunction cells, either the first average dopant dose or the second average dopant dose is at least approximately equal.

9. The transistor device of claim 3,
wherein the at least two groups of superjunction cells are different from each other in terms of both the first average dopant dose and the second average dopant dose.

10. The transistor device of claim 1,
wherein each first region of each superjunction cell has a first section and a second section,
wherein each second region of each superjunction cell has a first section and a second section,
wherein the first section of the first region is adjacent to the first section of the second region,
wherein the second section of the first region is adjacent to the second section of the second region,
wherein, in the first region, an average dopant dose of the first section is different from an average dopant dose of the second section, and
wherein, in the second region, an average dopant dose of the first section is different from an average dopant dose of the second section.

11. The transistor device of claim 10,
wherein, in the first region, the average dopant dose of the first section is lower than an average dopant dose of the second section, and
wherein in the second region, the average dopant dose of the first section is higher than an average dopant dose of the second section.

12. The transistor device of claim 10,
wherein, the average dopant dose of the first section of the first region is lower than the average dopant dose of the first section of the second region; and second section, and
wherein, the average dopant dose of the second section of the first region is higher than the average dopant dose of the second section of the second region.

13. The transistor device of claim 9,
wherein each superjunction cell has a width in the first direction; and
wherein the superjunction cells at least approximately have the same width.

14. The transistor device of claim 1,
wherein the semiconductor body comprises monocrystalline silicon carbide.

15. The transistor device of claim 1,
wherein each transistor cell comprises:
a source region of the first doping type;
a body region of the second doping type; and
a gate electrode arranged adjacent to the body region and dielectrically insulated from the body region by a gate dielectric,
wherein the body region is arranged between the source region and the current spreading region.

16. The transistor device of claim 13,
wherein each transistor cell further comprises a current spreading region adjoining at least one first region.

17. The transistor device of claim 15,
wherein the gate electrodes of the transistor cells each extends longitudinally in a second direction perpendicular to the first direction,
wherein the superjunction cells each extend longitudinally in a third direction, and
wherein the second direction at least approximately equals the third direction.

18. The transistor device of claim 15,
wherein the gate electrodes of the transistor cells each extends longitudinally in a second direction perpendicular to the first direction,
wherein the superjunction cells each extend longitudinally in a third direction, and
wherein the second direction is at least approximately perpendicular to the third direction.

19. A transistor device, comprising:
a drain node and a source node;
a superjunction region arranged in a semiconductor body and comprising a plurality of superjunction cells each comprising a first region of a first doping type and a second region of a second doping type complementary to the first doping type; and
a plurality of transistor cells;
wherein the first and second regions are arranged alternately in a first direction of the semiconductor body;
wherein the second regions are coupled to the source node;
wherein each of the first regions is coupled to the source node via at least one of the transistor cells and is coupled to the drain node;
wherein the superjunction cells comprise at least two different groups of superjunction cells;
wherein each superjunction cell has a first average dopant dose and a second average dopant dose; and
wherein the superjunction cells of the at least two different groups are different from each other in terms of at least one of the first and second average dopant doses.

20. A transistor device, comprising:
a drain node and a source node;
a superjunction region arranged in a semiconductor body and comprising a plurality of superjunction cells each comprising a first region of a first doping type and a second region of a second doping type complementary to the first doping type; and
a plurality of transistor cells;
wherein the first and second regions are arranged alternately in a first direction of the semiconductor body;
wherein the second regions are coupled to the source node;
wherein each of the first regions is coupled to the source node via at least one of the transistor cells and is coupled to the drain node;
wherein each superjunction cell has a first average dopant dose and a second average dopant dose; and
wherein at least some of the superjunction cells are balanced such that the first average dopant dose at least approximately equals the second average dopant dose.
